(19) United States
(12) Patent Application Publication
(10) Pub. No.: US 2024/0213269 A1
(43) Pub. Date: Jun. 27, 2024

(54) ARRAY SUBSTRATE AND DISPLAY PANEL

(71) Applicants: Beijing BOE Display Technology Co., Ltd., Beijing (CN); BOE Technology Group Co., Ltd., Beijing (CN)

(72) Inventors: Chongyang ZHAO, Beijing (CN); Yingmeng MIAO, Beijing (CN); Lingdan BO, Beijing (CN); Yingying QU, Beijing (CN); Dongchuan CHEN, Beijing (CN); Jiantao LIU, Beijing (CN)

(21) Appl. No.: 18/557,426

(22) PCT Filed: Oct. 22, 2021
(86) PCT No.: PCT/CN2021/125509

§ 371 Date: Oct. 26, 2023

(30) Foreign Application Priority Data
Apr. 29, 2021 (CN) 202110474950.8

(51) Int. Cl. H01L 27/12; G02F 1/1333; G02F 1/1335; G02F 1/1343; G02F 1/1362; G02F 1/1368

(52) U.S. Cl. CPC H01L 27/124; G02F 1/133345; G02F 1/133512; G02F 1/134363; G02F 1/136286; G02F 1/1368

(57) ABSTRACT

The present application relates to the technical field of display. Disclosed are an array substrate and a display panel. The array substrate comprises: a substrate, and scanning lines, scanning signal lines, data line pairs, thin film transistors and pixel electrodes, which are arranged on the substrate, wherein the substrate has a display area, and the display area comprises sub-pixel areas, which are distributed in an array; two adjacent scanning lines form a scanning line group, the scanning signal lines extend in a column direction, and one scanning signal line is electrically connected to only two scanning lines in one scanning line group; each data line pair comprises two data lines, sub-pixel columns are provided in one-to-one correspondence with the data line pairs, and the two data lines in each data line pair pass through corresponding sub-pixel areas in the column direction; and in a row direction, a light-shielding strip is provided between every two adjacent sub-pixel areas. In the array substrate, data lines pass through corresponding sub-pixel areas, and light-shielding strips are provided between sub-pixel areas in a row direction so as to shield light, such that light effect areas of the sub-pixel areas are effectively enlarged, and light transmittance is improved.

### CROSS-REFERENCE TO RELATED APPLICATIONS

The disclosure is a National Stage of International Application No. PCT/CN2021/125509, filed on Oct. 22, 2021, which claims the priority of the Chinese patent application No. 202110474950.8, filed with the China Patent Office on Apr. 29, 2021 and named “Array Substrate and Display Panel”, the entire contents of which are incorporated herein by reference.

### TECHNICAL FIELD

The present disclosure relates to the field of display technology, and in particular to an array substrate and a display panel.

### BACKGROUND

With the continuous development of the display technology, a liquid crystal display (LCD) display has occupied a dominant position in the display industry, and products using the advanced super dimension switch (ADS) structure have become the mainstream display mode due to their advantages such as the wide viewing angle, fast response speed, and high contrast. For the current full-screen products with a larger load than conventional products, especially to achieve ultra-high resolution levels, such as 8K level and 12K level, the products will face difficulties in driving, and it is necessary to use 2G2D (two gate lines drive simultaneously and two data lines drive simultaneously) pixel architecture to drive the pixels.

### SUMMARY

The present disclosure provides an array substrate. The array substrate includes: a substrate, where the substrate has a display area, and the display area includes a plurality of sub-pixel areas distributed in an array; scan lines on the substrate; where each of the scan lines is disposed between two rows of the sub-pixel areas and extends in a row direction; two adjacent scan lines form a scan line group; and in any two scan line groups, the scan lines in one of the any two scan line groups and the scan lines in other of the any two scan line groups are different from each other; scan signal lines, where the scan signal lines extend along a column direction; each of the scan signal lines is disposed between two adjacent columns of the sub-pixel areas; and one of the scan signal lines is only electrically connected to two scan lines of one scan line group; data line pairs on the substrate; where each of the data line pairs includes two data lines spaced apart and arranged in parallel; the data lines extend along the column direction; sub-pixel columns are in one-to-one correspondence with the data line pairs; and in a sub-pixel column and a data line pair which are mutually corresponding, two data lines in the data line pair pass through a corresponding sub-pixel area along the column direction; a thin film transistor, where the thin film transistor is electrically connected to the scan line and electrically connected to the data line; a pixel electrode; where the pixel electrode is located in the sub-pixel area and electrically connected to the thin film transistor, and an orthographic projection of the pixel electrode on the base substrate overlaps with orthographic projections of two corresponding data lines on the base substrate; and a light shielding strip, which is disposed between every two adjacent sub-pixel areas along the row direction.

In the above array substrate, the substrate includes a display area, and a wiring area is disposed on the peripheral side of the display area. The display area includes a plurality of sub-pixel areas distributed in an array, the plurality of sub-pixel areas are distributed in rows and columns, and the row direction and the column direction are mutually perpendicular to each other. The scan lines are arranged on the substrate and extend along the row direction, the plurality of scan lines are spaced sequentially along the column direction, and each scan line is located between two adjacent rows of sub-pixel areas. Every two adjacent scan lines form one scan line group, and the two scan lines in each scan line group are different from the scan lines in other scan line groups. A plurality of scan signal lines are arranged on the substrate and extend along the column direction, each scan signal line may be disposed between two adjacent columns of the sub-pixel areas, and one scan signal line only corresponds to two scan lines of one scan line group and is electrically connected with the two corresponding scan lines. Specifically, the scan signal lines can be evenly distributed on the substrate, and each scan signal line is electrically connected to the two corresponding scan lines for providing electrical signals to the scan lines. That is, when the scan lines are scanned, the scan signal line can provide electrical signals to the two scan lines simultaneously and drive two scan lines at the same time; and the scan signal lines extend along the column direction, and the drive circuit of the scan lines can be introduced into one side of the substrate along the column direction, thereby reducing the frame widths of the other three sides of the substrate. A plurality of data line pairs are arranged on the substrate, each data line pair includes two data lines spaced apart, and the data lines extend along the column direction and are arranged along the row direction. The data line pairs are in one-to-one correspondence with the sub-pixel columns; and in a data line pair and a sub-pixel column which are mutually corresponding, the two data lines in the data pair pass through the corresponding sub-pixel area along the column direction. The data line in the display area can be divided into two parts; and along the column direction, one part is opposite to the sub-pixel area, and the other part is opposite to the interval between two adjacent sub-pixel areas, where the part corresponding to the sub-pixel area in each data line overlaps with the sub-pixel area. A pixel electrode is disposed in the sub-pixel area, and the pixel electrode overlaps with the two data lines in the data line pair. In the sub-pixel area, except for the area shielded by the data lines, other areas are all light effect areas. In the sub-pixel areas arranged along the row direction, a light shielding strip is provided between every two adjacent sub-pixel areas, and the light shielding strip is used for shielding the interval between two adjacent sub-pixels in the row direction, to avoid light leakage and color mixing. Compared with the prior art that the two data lines in the data line pair are arranged in two sides of the sub-pixel area, that is, two data lines are disposed in the interval between two adjacent sub-pixel areas in the row direction, which increases the spacing distance between the two sub-pixel areas and increases the width of the light shielding area arranged along the column direction because the two data lines are needed to be separated by a certain distance to avoid the risk of short circuit, and reduces the light effect areas of the sub-pixel areas because these light shielding areas have no light effect and crowd out the light effect areas of the sub-pixel areas, in the embodiments, the data lines pass through the sub-pixel, and the light shielding strip extends along the column direction and is arranged between adjacent sub-pixel areas, so the light shielding strip can avoid color mixing between the sub-pixel areas in the column direction, and the width of the light shielding strip along the row direction can be reduced, which greatly reduces the light shielding width between the two sub-pixel areas in the row direction, effectively increases the light effect area of the sub-pixel area and improves the light transmittance. The light transmittance of the sub-pixel areas in the above array substrate can have great improvement compared with the pixel structure in the prior art. The above array substrate is applied to a high-resolution full-screen product, which can effectively solve the problem of low light transmittance of the high-resolution full-screen product, improving the light transmittance of the high-resolution full-screen product.

Optionally, an organic insulating layer is disposed between the data lines and the pixel electrode for isolation.

Optionally, the array substrate further includes a common electrode corresponding to the pixel electrode, and a common electrode line electrically connected to the common electrode.

Optionally, the common electrode is on a side away from the substrate, of the data lines; the pixel electrode is on a side away from the data lines, of the common electrode; the organic insulating layer is between the data lines and the common electrode; and a passivation layer is disposed the common electrode and the pixel electrode for isolation.

Optionally, the light shielding strip is a metal light shielding strip, and the metal light shielding strip is electrically connected to the common electrode line.

Optionally, the light shielding strip and the scan lines are prepared on the same layer.

Optionally, the thin film transistor includes a gate, a gate insulating layer, an active layer, an insulating layer, and source and drain electrodes electrically connected to the active layer which are stacked in sequence; where the gate and the scan lines are prepared on the same layer; and the source and drain electrodes are disposed on the same layer as the data lines.

Optionally, in the scan signal lines, a part of the scan signal lines are non-electrically connected to the scan lines, and a part of the scan signal lines are electrically connected to the common electrode lines.

Optionally, the scan signal lines and the data lines are prepared on the same layer.

Optionally, the pixel electrode includes a plurality of electrode strips arranged at intervals and connected in sequence.

Optionally, the array substrate further includes a light shielding layer disposed along the row direction and corresponding to the scan lines for shielding light.

The present disclosure also provides a display panel including any one of the array substrates in the above technical solutions.

### BRIEF DESCRIPTION OF FIGURES

FIG. 1 is a schematic diagram of a partial structure of an array substrate according to an embodiment of the present disclosure.

FIG. 2 is a schematic structural diagram of a sub-pixel in an array substrate according to an embodiment of the present disclosure.

FIG. 3 is a schematic structural diagram of a sub-pixel in an array substrate according to an embodiment of the present disclosure.

### DETAILED DESCRIPTION

The technical solutions of the embodiments of the present disclosure will be clearly and completely described below in conjunction with the drawings of the embodiments of the present disclosure. Obviously, the described embodiments are some, but not all, of the embodiments of the present disclosure. Based on the embodiments of the present disclosure, all other embodiments obtained by those of ordinary skill in the art without creative efforts fall within the scope of protection of the present disclosure.

For the ultra-high-resolution product, due to its high resolution, small pixel size, and low transmittance, if it is made into a full-screen product, it is necessary to increase the gate signal line parallel to the data line in the pixel to transmit the signal to the gate line, and the transmittance drop will be more obvious. Therefore, how to improve the light transmittance of high-resolution full-screen products is an urgent problem to be solved.

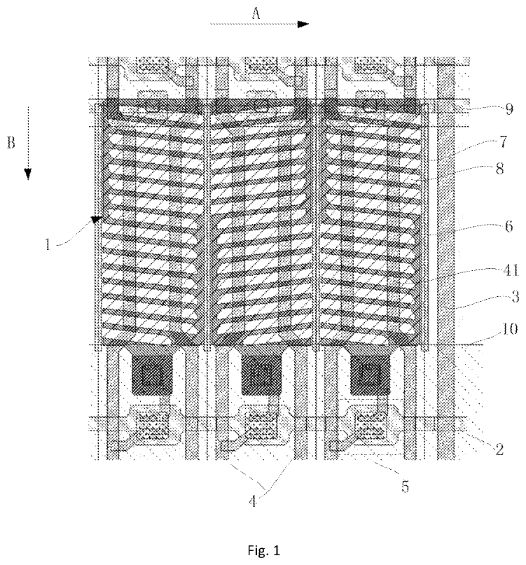

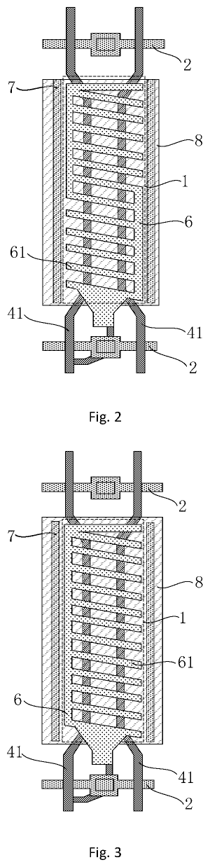

As shown in FIGS. 1-2, a row direction is shown as the A direction in FIG. 1, and a column direction is shown as the B direction in FIG. 1. Embodiments of the present disclosure provide an array substrate, including: a substrate, where the substrate has a display area, and the display area includes a plurality of sub-pixel areas 1 distributed in an array; scan lines 2 on the substrate, where each scan line 2 is between two rows of sub-pixel areas and extends in the row direction, two adjacent scan lines form a scan line group, and in any two scan line groups, the scan lines in one scan line group and the scan lines in the other scan line group are different from each other; that is, a plurality of scan lines are divided into a plurality of scan line groups, two scan lines in each scan line group are adjacent, no scan line in two adjacent scan line groups is shared, and the scan lines in the two scan line groups are different from each other; scan signal lines 3 which extend along the column direction, where each of the scan signal lines 3 is between two adjacent columns of the sub-pixel areas, and one scan signal line 3 is only electrically connected with two scan lines 2 in one scan line group; data line pairs 4 on the substrate, where each data line pair 4 includes two data lines 41 spaced apart and arranged in parallel, the data lines 41 extend in the column direction, the sub-pixel columns are in one-to-one correspondence with the data line pairs, in the sub-pixel column and the data line pair which are mutually corresponding, the two data lines 41 in the data line pair pass through the corresponding sub-pixel area 1 along the column direction; a thin film transistor 5, where the thin film transistor 5 is electrically connected to the scan line 2 and electrically connected to the data line 41; a pixel electrode 6, where the pixel electrode 6 is in the sub-pixel area 1 and electrically connected to the thin film transistor 5, and an orthographic projection of the pixel electrode 6 on the base substrate overlaps with orthographic projections of two corresponding data lines 41 on the base substrate; and a light shielding strip 7, which is disposed between every two adjacent sub-pixel areas along the row direction.

The above array substrate includes a substrate; and scan lines, scan signal lines, data lines, thin film transistors, and pixel electrodes arranged on the substrate. The substrate includes a display area, and a wiring area is disposed on the peripheral side of the display area. The display area includes a plurality of sub-pixel areas distributed in an array, the plurality of sub-pixel areas are distributed in rows and columns, and the row direction and the column direction are mutually perpendicular to each other. The scan lines are arranged on the substrate and extend along the row direction, the plurality of scan lines are spaced sequentially along the column direction, and each scan line is between two adjacent rows of sub-pixel areas. Every two adjacent scan lines form one scan line group, a plurality of scan lines form a plurality of scan line groups, and the two scan lines in each scan line group are different from the scan lines in other scan line groups. A plurality of scan signal lines are also arranged on the substrate and extend along the column direction, each scan signal line may be disposed between two adjacent columns of the sub-pixel areas, and one scan signal line only corresponds to two scan lines of one scan line group and is electrically connected with the two corresponding scan lines. Specifically, the scan signal lines can be evenly distributed on the substrate, and each scan signal line is electrically connected to the two corresponding scan lines for providing electrical signals to the scan lines. That is, when the scan signal lines are scanned, the scan signal line can provide electrical signals to the two scan lines simultaneously and drive two scan lines at the same time; and the scan signal lines extend along the column direction, and the drive circuit of the scan lines can be introduced into one side of the substrate along the column direction, thereby reducing the frame widths of the other three sides of the substrate. A plurality of data line pairs are arranged on the substrate, each data line pair includes two data lines spaced apart, and the data lines extend along the column direction and are arranged along the row direction. The data line pairs are in one-to-one correspondence with the sub-pixel columns; and in a data line pair and a sub-pixel column which are mutually corresponding, the two data lines in the data pair pass through the corresponding sub-pixel area along the column direction. The data line in the display area can be divided into two parts; and along the column direction, one part is opposite to the sub-pixel area, and the other part is opposite to the interval between two adjacent sub-pixel areas, where the part corresponding to the sub-pixel area in each data line overlaps with the sub-pixel area. A pixel electrode is disposed in the sub-pixel area, and the pixel electrode overlaps with the two data lines in the data line pair. In the sub-pixel area, except for the area shielded by the data lines, other areas are all light effect areas, where the light effect area here refers to an area in the sub-pixel area that can effectively transmit light. In the sub-pixel areas arranged along the row direction, a light shielding strip is provided between every two adjacent sub-pixel areas, and the light shielding strip is used for shielding the interval between two adjacent sub-pixels in the row direction, to avoid light leakage and color mixing. Compared with the related art that the two data lines in the data line pair are arranged in two sides of the sub-pixel area, that is, two data lines are disposed in the interval between two adjacent sub-pixel areas in the row direction, which increases the spacing distance between the two sub-pixel areas and increases the width of the light shielding area arranged along the column direction because the two data lines are needed to be separated by a certain distance to avoid the risk of short circuit, and reduces the light effect areas of the sub-pixel areas because these light shielding areas have no light effect and crowd out the light effect areas of the sub-pixel areas; however in the embodiments, the data lines pass through the sub-pixel, and the light shielding strip extends along the column direction and is arranged between adjacent sub-pixel areas, so the light shielding strip can avoid color mixing between the sub-pixel areas in the column direction, and the width of the light shielding strip along the row direction can be reduced, which greatly reduces the light shielding width between the two sub-pixel areas in the row direction, effectively increases the light effect area of the sub-pixel area and improves the light transmittance. The light transmittance of the sub-pixel areas in the above array substrate can have great improvement compared with the pixel structure in the prior art. The above array substrate is applied to a high-resolution full-screen product, which can effectively solve the problem of low light transmittance of the high-resolution full-screen product, improving the light transmittance of the high-resolution full-screen product.

Therefore, in the above array substrate, the data lines in the data line pair pass through the corresponding sub-pixel area, and the light shielding strip is arranged between the sub-pixel areas in the row direction for shielding light, which effectively increases the light effect areas of the sub-pixel areas and improves the light transmittance.

Specifically, in the above array substrate, an organic insulating layer is disposed between the data lines and the pixel electrode for isolation. For the layer structure arrangement on the substrate, in the stacking direction of the layer structure of the data lines and the pixel electrode, an organic insulating layer is disposed between the data lines and the pixel electrode for isolating each other, and the layer thickness of the organic insulating layer can be appropriately increased based on actual needs, which can weaken or even avoid the electric field between the data lines and the pixel electrode, prevent the voltage pull on the pixel electrode when the voltage of the data lines jump, avoid bad signal crosstalk, and avoid affecting the display effect, and is conductive to ensure normal display effect.

In some embodiments, as shown in FIG. 1, the above array substrate further includes a common electrode 8 corresponding to the pixel electrode, and a common electrode line 9 electrically connected to the common electrode 8. The common electrode line provides a stable voltage to the common electrode to ensure normal display function.

In some embodiments, the common electrode is disposed on the substrate, the common electrode is on a side away from the substrate, of the data lines, the pixel electrode is on a side away from the data lines, of the common electrode, the organic insulating layer is between the data lines and the common electrode, and a passivation layer is disposed between the common electrode and the pixel electrode for isolation. That is, along the stacking direction of the layer structure on the substrate, the common electrode is between the data lines and the pixel electrode, the organic insulating layer is disposed between the common electrode and the data lines for isolation, and the passivation layer is disposed between the common electrode and the pixel electrode for isolation. The common electrode is between the data lines and the pixel electrode, which can effectively shield the electric field between the data lines and the pixel electrode, and prevent voltage pulling on the pixel electrode when the voltage of the data lines jump and bad signal crosstalk, effectively ensuring the normal display of the sub-pixels. The common electrode is disposed between the data lines and the pixel electrode to shield the electric field between the two, so the thickness of the organic insulating layer between the data lines and the common electrode can be appropriately set to be smaller, the organic insulating layer only plays a role in insulating, and there is no need to rely on the organic insulating layer to shield the electric field between the data lines and the pixel electrode, which can be helpful to reduce the thickness of the display panel and is conductive to the thin and light design of the display panel.

In some embodiments, the light shielding strip is a metal light shielding strip, and the metal light shielding strip is electrically connected to the common electrode line. The light shielding strips and the common electrode lines can be connected through via holes, which results in the better uniformity of the common electrical signals of the common electrodes on the substrate.

In some embodiments, the light shielding strips and the scan lines may be prepared on the same layer, that is, the light shielding strips and the scan lines can be formed on the same metal layer when prepared by patterning, which can save the preparation procedure and simplify the preparation process.

In some embodiments, in the above array substrate, the thin film transistor includes a gate, a gate insulating layer, an active layer, an insulating layer, and source and drain electrodes electrically connected to the active layer which are stacked in sequence; where the gate and the scan lines may be prepared on the same layer, the source and drain electrodes may be disposed on the same layer as the data lines, and the drain of the thin film transistor is electrically connected to the pixel electrode through the via hole.

In some embodiments of the above array substrate, for the number of scan signal lines and the corresponding arrangement relationship between the scan signal lines and the scan line groups, there are a plurality of scan signal lines, and the same scan signal line corresponds to two scan lines of the only one scan line group. In terms of the number of scan signal lines, the number of scan signal lines is at least half of the number of scan lines, that is, the number of scan signal lines exactly corresponds to the number of scan line groups, to achieve electrical signal driving for two scanning lines at the same time. Alternatively, the number of scan signal lines may be more than the number of scan line groups; and in addition to the scan signal lines electrically connected to the scan lines, a part of the scan signal lines is idle. The idle scan signal lines are not electrically connected to the scan lines, and can be electrically connected to the common electrode lines, which can further improve the uniformity of the common electrical signals of the common electrodes of the display panel. Alternatively, when the number of scan signal lines is more than the number of scan line groups, for example, when the number of scan signal lines is multiple times the number of scan line groups, two or three scan signal lines can be set to correspond to one scan line group; that is, two or three scan signal lines are respectively connected to the same scan line group, and two or three scan signal lines simultaneously provide scan signals to one scan line group, which can effectively reduce the resistance value.

In order to ensure the consistency of the pixel aperture ratio, a scan signal line can be disposed between two adjacent pixel units, where, it is necessary to ensure that one scan signal line corresponds to and is electrically connected to one scan line group, and the scan signal line that is not connected to the scan line may be connected to the common electrode line. It should be noted that the above one scan signal line only corresponds to one scan line group, which means that the same scan signal line can only correspond to one scan line group, that is, only one scan signal line is connected to one scan line group. However, one scan line group can be connected to two or more different scan signal lines at the same time; and when there are too many scan signal lines, two different scan signal lines can be connected to the same scan line group respectively, two different scan signal lines provide scan signals to the same scan line group at the same time, and one scan line group may correspond to more scan signal lines.

In some embodiments, in order to facilitate the description of the number and distribution of the scan signal lines, the following is illustrated with a pixel structure with 8K resolution and pixel units are 7680×4320 in the row direction and the column direction. Where, in the row direction, 7680 pixel units are arranged in each row, and three sub-pixels are arranged in each pixel unit along the row direction; and in the column direction, 4320 pixel units are arranged in each column.

For the above pixel structure of 8K resolution, there may be 2160 scan line groups, only 2160 scan signal lines may be arranged, and the scan signal lines are arranged in one-to-one correspondence with the scan line groups.

Alternatively, one scan signal line may be disposed on one side of each column of pixel units, and one scan signal line is provided for each pixel unit. The scan signal lines are evenly arranged in the display panel, which is beneficial to improve the consistency of the pixel aperture ratio. So there are 7680 scan signal lines, and 7680 is triple 2160 with a remainder of 1200. Therefore, three scan signal lines may be connected to two scan lines of the same scan line group, where each scan signal line is connected to two scan lines of the scan line group; that is, three scan signal lines provide scan signals to two scan lines of one scan line group at the same time. The 1200 excess scan signal lines may be electrically connected to the common electrode lines.

In some embodiments, the scan signal lines and the data lines are prepared on the same layer, and the scan signal lines may be electrically connected to the scan lines through via holes. The same metal layer is patterned to form the scan signal lines and the data lines at the same time, saving one mask and reducing the preparation procedure. It should be noted that the scan signal lines and the data lines may also be prepared on different layers, that is, the scan signal line and the data line are prepared on two layers of metal layers by using different masks. The preparation of the scan signal lines is not limited in the embodiments.

In some embodiments, in order to avoid the short circuit caused by the shorter distance between the two data lines in the data pair, a certain spacing distance is required between the two data lines in each data line pair. The spacing distance between the two data lines in the data line pair is set to be greater than or equal to 5 μm, specifically, the spacing distance between the two data lines here refers to the distance between the adjacent sides of the two data lines. The spacing distance between two data lines in the data line pair is set to be greater than or equal to 5 μm, which can effectively avoid the problem of poor short circuit. In some embodiments, the spacing distance between the two data lines is related to factors such as the thickness and the material of the data lines, and as long as no short circuit occurs between two adjacent data lines, the spacing distance between the two data lines in the data line pair may be set to 6 μm, 7 μm, 7.5 μm, 8 μm, 9 μm or other values, which are not limited in the implementation.

It should be noted that, according to the arrangement of the data lines in the embodiments, in two adjacent data line pairs, the spacing distance between two adjacent data lines which belong to different data line pairs is also greater than or equal to 7 μm. According to the pixel structure arrangement in the embodiments, during the structure arrangement, the spacing distance between two adjacent data lines which belong to different data line pairs is definitely large, and is greater than 7 μm, which generally does not cause the problem of short circuit.

In some embodiments, as shown in FIG. 1, the above array substrate further includes a light shielding layer 10 disposed along the row direction and corresponding to the scan lines for shielding light. The light shielding layer here forms a light shielding black matrix, and along the row direction of the substrate, the light shielding layer is disposed to shield the scan lines and the light leakage area between the scan line and the sub-pixel area, which can effectively avoid color mixing.

In some embodiments, as shown in FIGS. 2 and 3, in order to further increase the light transmittance, the pixel electrode 6 may has a plurality of electrode strips 61 arranged at intervals and connected in sequence, where the plurality of electrode strips 61 are sequentially spaced and arranged side by side. From the arrangement direction of the plurality of electrode strips, the same ends of a part of the electrode strips are sequentially connected, the other end of another part of the electrode strips are sequentially connected, and both ends of the electrode strips in the middle location are connected, so that the two parts of the electrode strips are electrically connected to form a Chinese character symbol “ [symbol] ”-shaped pixel electrode as shown in FIG. 2, which can effectively improve the light transmittance of the pixels. It should be noted that the same ends of a plurality of electrode strips in the pixel electrode are sequentially connected to form a comb-shaped pixel electrode, as shown in FIG. 3. Alternatively, the plurality of electrode strips may also be connected in other ways to form other shape structures, which is not limited in the embodiments.

Some embodiments also provide a display panel including any of the array substrates provided in the foregoing embodiments. The display panel in the embodiments is an ADS display panel, and in the pixel structure of the display panel, the light effect areas of the sub-pixel areas are increased, which effectively improves the light transmittance. Compared with the ADS display panel in the related art, the light transmittance of the display panel in the embodiments may be effectively increased by more than 26%. In addition, compared with the existing in-plane switching (IPS) display panel, the transmittance of the display panel in the embodiments is also increased by more than 20%, which effectively solves the problem of low transmittance in the current high-resolution full-screen products, and improves the light transmittance of high-resolution full-screen products.

Obviously, those skilled in the art can make various changes and modifications to the disclosure without departing from the spirit and scope of the disclosure. In this way, if these modifications and variations of the disclosure fall within the scope of the claims of the disclosure and equivalent technologies, the disclosure is also intended to include these modifications and variations.

1. An array substrate, comprising:
a substrate; wherein the substrate comprises a display area, and the display area comprises a plurality of sub-pixel areas distributed in an array;
scan lines on the substrate; wherein each of the scan lines is disposed between two adjacent rows of the sub-pixel areas and extends in a row direction; two adjacent scan lines form a scan line group; and in any two scan line groups, the scan lines in one of the any two scan line groups and the scan lines in other of the any two scan line groups are different from each other;
scan signal lines, wherein the scan signal lines extend along a column direction; each of the scan signal lines is disposed between two adjacent columns of the sub-pixel areas; and one of the scan signal lines is only electrically connected to two scan lines of one scan line group;
data line pairs on the substrate; wherein each of the data line pairs comprises two data lines spaced apart and arranged in parallel; the data lines extend along the column direction; sub-pixel columns are in one-to-one correspondence with the data line pairs; and in a sub-pixel column and a data line pair which are mutually corresponding, two data lines in the data line pair pass through a corresponding sub-pixel area along the column direction;
a thin film transistor, wherein the thin film transistor is electrically connected to the scan line and electrically connected to the data line;
a pixel electrode; wherein the pixel electrode is in the sub-pixel area and electrically connected to the thin film transistor, and an orthographic projection of the pixel electrode on the base substrate overlaps with orthographic projections of two corresponding data lines on the base substrate; and
a light shielding strip, which is disposed between every two adjacent sub-pixel areas along the row direction.

2. The array substrate according to claim 1, wherein an organic insulating layer is disposed between the data lines and the pixel electrode for isolation.

3. The array substrate according to claim 2, further comprising:
a common electrode corresponding to the pixel electrode; and
a common electrode line electrically connected to the common electrode.

4. The array substrate according to claim 3, wherein the common electrode is on a side away from the base substrate, of the data lines;
the pixel electrode is on a side away from the data lines, of the common electrode;
the organic insulating layer is between the data lines and the common electrode; and
a passivation layer is disposed between the common electrode and the pixel electrode for isolation.

5. The array substrate according to claim 3, wherein the light shielding strip is a metal light shielding strip, and the metal light shielding strip is electrically connected to the common electrode line.

6. The array substrate according to claim 5, wherein the light shielding strip and the scan lines are prepared on a same layer.

7. The array substrate according to claim 1, wherein the thin film transistor comprises a gate, a gate insulating layer, an active layer, an insulating layer, and source and drain electrodes electrically connected to the active layer which are stacked in sequence;
wherein the gate and the scan lines are prepared on a same layer; and the source and drain electrodes are disposed on a same layer as the data lines.

8. The array substrate according to claim 3, wherein, in the scan signal lines, a part of the scan signal lines are non-electrically connected to the scan lines, and a part of the scan signal lines are electrically connected to the common electrode lines.

9. The array substrate according to claim 1, wherein the scan signal lines and the data lines are prepared on a same layer.

10. The array substrate according to claim 1, wherein the pixel electrode comprises a plurality of electrode strips arranged at intervals and connected in sequence.

11. The array substrate according to claim 1, further comprising a light shielding layer disposed along the row direction and corresponding to the scan lines for shielding light.

12. A display panel, comprising an array substrate, wherein the array substrate comprising:
a substrate; wherein the substrate comprises a display area, and the display area comprises a plurality of sub-pixel areas distributed in an array;
scan lines on the substrate; wherein each of the scan lines is disposed between two adjacent rows of the sub-pixel areas and extends in a row direction; two adjacent scan lines form a scan line group; and in any two scan line groups, the scan lines in one of the any two scan line groups and the scan lines in other of the any two scan line groups are different from each other;
scan signal lines, wherein the scan signal lines extend along a column direction; each of the scan signal lines is disposed between two adjacent columns of the sub-pixel areas; and one of the scan signal lines is only electrically connected to two scan lines of one scan line group;
data line pairs on the substrate; wherein each of the data line pairs comprises two data lines spaced apart and arranged in parallel; the data lines extend along the column direction; sub-pixel columns are in one-to-one correspondence with the data line pairs; and in a sub-pixel column and a data line pair which are mutually corresponding, two data lines in the data line pair pass through a corresponding sub-pixel area along the column direction;
a thin film transistor, wherein the thin film transistor is electrically connected to the scan line and electrically connected to the data line;
a pixel electrode; wherein the pixel electrode is in the sub-pixel area and electrically connected to the thin film transistor, and an orthographic projection of the pixel electrode on the base substrate overlaps with orthographic projections of two corresponding data lines on the base substrate; and
a light shielding strip, which is disposed between every two adjacent sub-pixel areas along the row direction.

13. The display panel according to claim 12, wherein an organic insulating layer is disposed between the data lines and the pixel electrode for isolation.

14. The display panel according to claim 13, further comprising:
a common electrode corresponding to the pixel electrode; and
a common electrode line electrically connected to the common electrode.

15. The display panel according to claim 14, wherein the common electrode is on a side away from the base substrate, of the data lines;
the pixel electrode is on a side away from the data lines, of the common electrode;
the organic insulating layer is between the data lines and the common electrode; and
a passivation layer is disposed between the common electrode and the pixel electrode for isolation.

16. The display panel according to claim 14, wherein the light shielding strip is a metal light shielding strip, and the metal light shielding strip is electrically connected to the common electrode line.

17. The display panel according to claim 16, wherein the light shielding strip and the scan lines are prepared on a same layer.

18. The display panel according to claim 12, wherein the thin film transistor comprises a gate, a gate insulating layer, an active layer, an insulating layer, and source and drain electrodes electrically connected to the active layer which are stacked in sequence;
wherein the gate and the scan lines are prepared on a same layer; and the source and drain electrodes are disposed on a same layer as the data lines.

19. The display panel according to claim 14, wherein, in the scan signal lines, a part of the scan signal lines are non-electrically connected to the scan lines, and a part of the scan signal lines are electrically connected to the common electrode lines.

20. The display panel according to claim 12, wherein the scan signal lines and the data lines are prepared on a same layer.
